(19) United States
(12) Patent Application Publication
(10) Pub. No.: US 2024/0336476 A1
(43) Pub. Date: Oct. 10, 2024

(54) Temperature Distribution of Microheater

(71) Applicants: Saudi Arabian Oil Company, Dhahran (SA); King Abdullah University of Science and Technology, Thuwal (SA)

(72) Inventors: Nadeem Qaiser, Thuwal (SA); Maha Nour, Thuwal (SA); Vincent Tung, Emeryville, CA (US)

(21) Appl. No.: 18/297,949

(22) Filed: Apr. 10, 2023

(51) Int. Cl. B81B 7/00; H05B 3/26; H05B 6/44

(52) U.S. Cl. CPC B81B 7/0096; H05B 3/26; H05B 6/44; H05B 2203/003

(57) ABSTRACT

Example methods and devices for improving uniformity of temperature distribution of a microheater or a microheater array are disclosed. One example method includes determining that a temperature of a first coil segment of multiple coil segments of a microheater is lower than a temperature of a second coil segment of the multiple coil segments, where the first coil segment is closer to an edge of the microheater than the second coil segment, and the microheater is a heating component of a microelectromechanical systems (MEMS) based device. A resistance of the first coil segment is increased through a reduction of a width of the first coil segment. After the reduction of the width of the first coil segment, a width of the second coil segment is adjusted based on a difference between the temperature of the first coil segment and the temperature of the second coil segment.

### TECHNICAL FIELD

The present disclosure relates to methods and devices for temperature distribution of microheater.

### BACKGROUND

One of the features of microelectromechanical systems (MEMS) based devices and components, for example, MEMS-based sensors, actuators, heaters, energy harvesting devices, and storage devices, includes their sub-millimeter or micrometer range of size. A microheater can have a coil of specific design or topology that includes multiple coil segments. The microheater can be placed on a thermally insulated substrate. Al2O3, SiO2, Si3N4, or polymer membranes can be used as insulated substrates. Joule heating governs the principle of the microheater, i.e., voltage or current can be applied to the electrical terminals or pads connected to the heating coil, which in turn generates heat due to its resistance to the current flow.

### SUMMARY

The present disclosure involves methods and devices for improving uniformity of temperature distribution of a microheater or a microheater array. One example method includes determining that a temperature of a first coil segment of multiple coil segments of a microheater is lower than a temperature of a second coil segment of the multiple coil segments, where the first coil segment is closer to an edge of the microheater than the second coil segment, and the microheater is a heating component of a microelectromechanical systems (MEMS) based device. A resistance of the first coil segment is increased through a reduction of a width of the first coil segment. After the reduction of the width of the first coil segment, a width of the second coil segment is adjusted based on a difference between the temperature of the first coil segment and the temperature of the second coil segment.

Some or all of the aspects may be methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example workflow of improving uniformity of temperature distribution of a microheater.

FIG. 2A illustrates an example of a fan-shaped platinum-based microheater with fixed coil width.

FIG. 2B illustrates an example of a fan-shaped platinum-based microheater with varying coil widths for different coil segments of the microheater.

FIG. 3 illustrates an example of optimized coil widths through numerical calculations for different coil segments of a microheater.

FIG. 4A illustrates an example of non-uniform temperature distribution along the profile of the microheater in FIG. 2A.

FIG. 4B illustrates an example of temperature distribution with improved uniformity along the profile of the microheater shown in FIG. 3.

FIG. 4C illustrates an example of displacement distribution with improved uniformity along the profile of the microheater shown in FIG. 3.

FIG. 4D illustrates an example of von Mises stress distribution with improved uniformity along the profile of the microheater shown in FIG. 3.

FIG. 5A illustrates an example of potential distribution of multiple concentric-shaped and platinum-based microheaters connected in a parallel circuit configuration.

FIG. 5B illustrates an example of temperature distribution of the microheater array in FIG. 5A.

FIG. 5C illustrates an example of potential distribution of multiple concentric-shaped platinum-based microheaters connected in a series circuit configuration.

FIG. 5D illustrates an example of temperature distribution of the microheater array in FIG. 5C.

FIG. 6A illustrates an example of the characteristics and representative schematics of series circuit.

FIG. 6B illustrates an example of the characteristics and representative schematics of parallel circuit.

FIG. 7A illustrates an example of temperature distribution of multiple concentric-shaped platinum-based microheaters connected in a hexagonal configuration.

FIG. 7B illustrates an example of displacement distribution of multiple concentric-shaped platinum-based microheaters connected in a hexagonal configuration.

FIG. 7C illustrates an example of temperature distribution of multiple concentric-shaped platinum-based microheaters connected in a diamond configuration.

FIG. 7D illustrates an example of displacement distribution of multiple concentric-shaped platinum-based microheaters connected in a diamond configuration.

FIG. 8 illustrates an example process of improving uniformity of temperature distribution of a microheater.

Like reference numbers and designations in the various drawings indicate like elements.

### DETAILED DESCRIPTION

This specification relates to improving uniformity of temperature distribution of a microheater as well as an array of microheaters. The input energy and corresponding output temperature of a microheater can vary based on the coil's material and geometrical topology, for example, the coil's width, thickness, and number of turns. Materials for heating coils can include polysilicon, platinum (Pt), copper, gold, silver, or aluminum. For the same material, the output temperature of a microheater can be controlled through topological design or layout of the coil. For instance, serpentine, fan-shaped, annular, concentric, or meander pattern can have variations in output temperatures for the same material and under identical boundary conditions. These variations can be caused by the coil's resistance, which relies on the coil's area, length, width, or layout. Devices such as gas sensors, bio-medical application related sensors, and micro-channel-based actuators and sensors may benefit from improved uniformity of output temperature along the surface area of a microheater.

In some implementations, to reduce variation in temperature distribution of a microheater, the widths of different segments of the coil of the microheater can be controlled. For an array of microheaters, this can be achieved by assembling the microheaters in the array in a series circuit configuration, which reduces variation in temperature distribution for the region of the array. The reduced variation in temperature distribution of a microheater can result in more efficient areal heating of the microheater.

In some implementations, when an extended area of interest needs to be heated, instead of using a single heater, multiple microheaters can be connected in a series configuration to improve uniformity of temperature distribution across the multiple microheaters, since enlarging a single heater to heat the extended area of interest may led to excessive input energy to produce the same temperature.

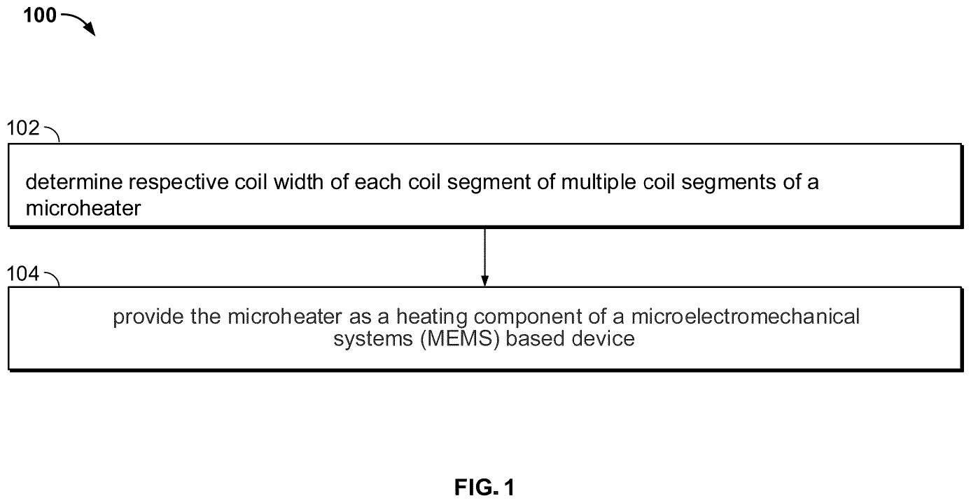

FIG. 1 illustrates an example workflow 100 of improving uniformity of temperature distribution of a microheater. At 102, a respective coil width of each coil segment of multiple coil segments of a microheater is determined. This can result in varying coil width of the microheater. The varying coil width can help improve uniformity of the temperature distribution of the microheater.

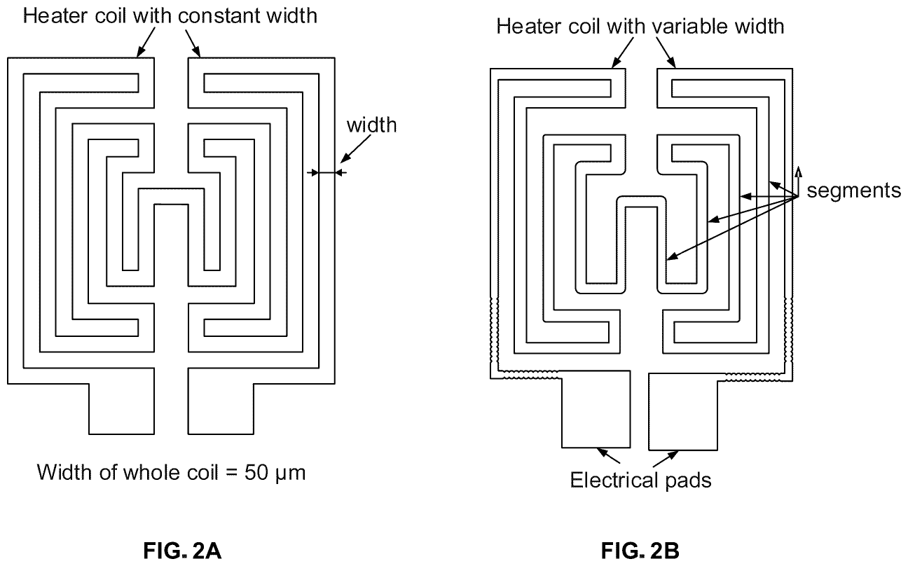

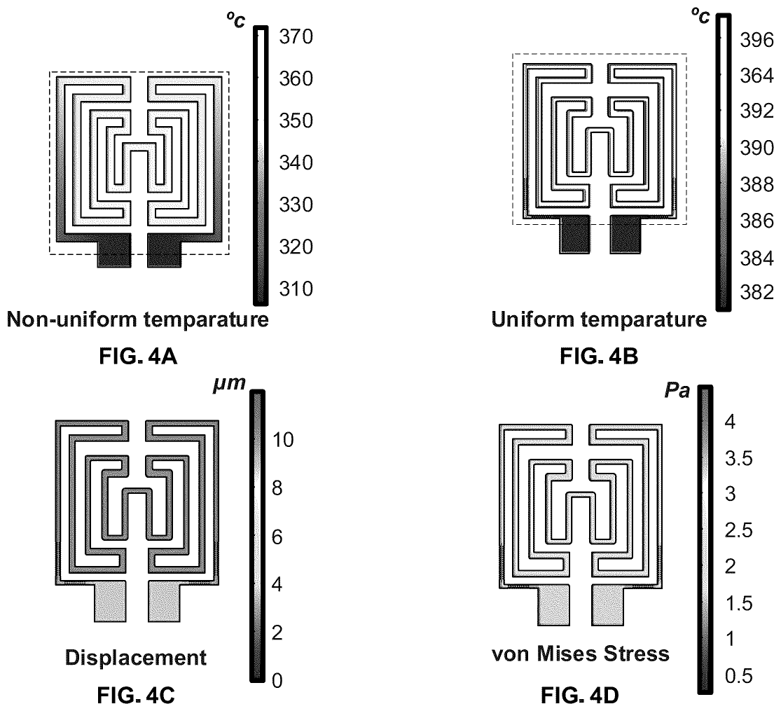

FIG. 2A illustrates an example of a fan-shaped platinum-based microheater with fixed coil width. The example design in FIG. 2A maintains a constant width of 50 μm for the coil of the microheater. The temperature distribution along the profile of the microheater of FIG. 2A can be non-uniform given the constant width for the coil of the microheater. FIG. 4A illustrates an example of non-uniform temperature distribution along the profile of the microheater in FIG. 2A. In FIG. 4A, the coil temperature along the profile of the microheater can vary from 305° C. to 370° C. Therefore the temperature distribution along the profile of the microheater in FIG. 2A has a 22% non-uniformity.

FIG. 2B illustrates an example of a fan-shaped platinum-based microheater with varying coil widths for different coil segments of the microheater. The varying coil widths can result in temperature distribution with improved uniformity along the profile of the microheater. The width of each coil segment of the microheater can be numerically calculated to achieve uniformity in temperature distribution along the profile of the micro heater. The numerically calculation of the width of each coil segment can be performed using finite element method (FEM), for example, using COMSOL FEM software program. Solid Mechanics, Heat Transfer, and Electrical Currents modules of the COMSOL FEM software program can be used in order to simulate the Joule Heat effect.

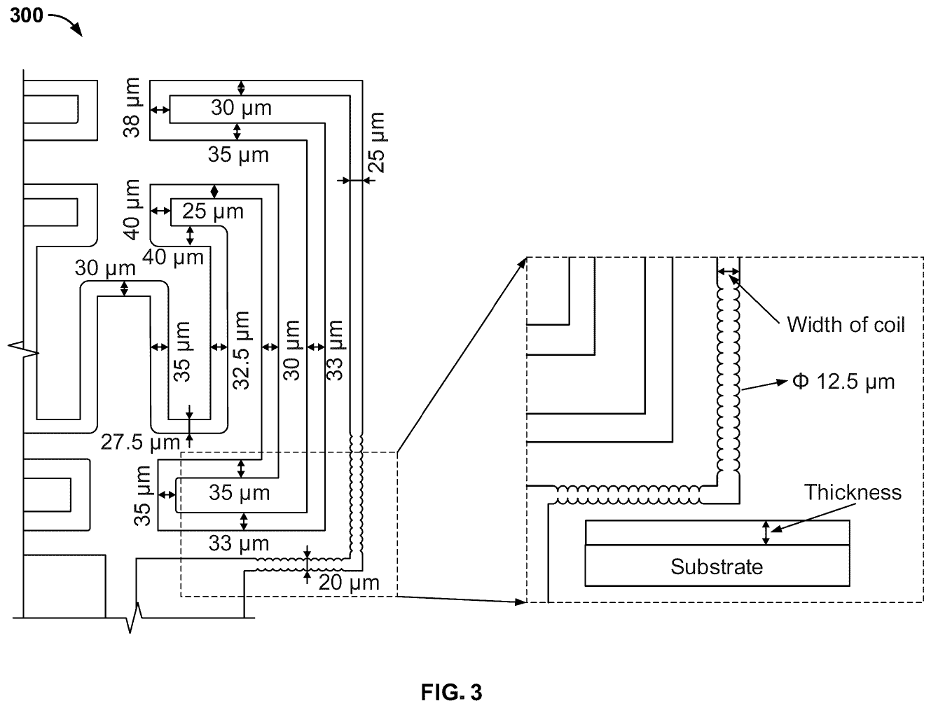

FIG. 3 illustrates an example 300 of optimized coil widths through numerical calculations for different coil segments of a microheater. The coil segment width and thickness of microheater are depicted in zoomed-inset of FIG. 3. An example thickness of a microheater can be 1 μm. An example size of a microheater can be 1000×1000 μm, which includes the width of each coil segment and the space among coil segments of the microheater. The example coil widths for different coil segments shown in FIG. 3 are scalable and can be applicable for microheaters of other sizes. When the numerical calculation of the coil width of each coil segment of the microheater is performed, the resistance at the outermost coil segment is increased as it has a lower temperature than the inner coil segments. The increase of the outermost coil segment's resistance is achieved by decreasing its coil's width.

In some implementations, the starting point of the coil (region or edge connected to electrical pads) can experience lower temperature than other coil segments of the microheater. Example electrical pads are shown in FIG. 2B. The resistance of a coil segment near the electrical pad can be increased by using a wavy structure for the coil segment near the electrical pad. The wavy structure can be a jagged-shape half-circled structure that increases the resistance of the coil segment near an electrical pad, and therefore temperature of the wavy structure can be increased to address the lower temperature deficiency of coil segment near the electrical pad that does not have wavy structure. The overall surface area of the whole microheater can remain the same. The wavy structure can start at the point where electrical pads ends and coil of microheater starts.

In some implementations, the diameter of each half circle in the wavy structure can be optimized by numerical calculations, for example, using finite element method. An example diameter of each half circle in the wavy structure can be 12.5 μm, as shown in the zoomed images of FIG. 3 inside the dotted rectangle.

FIG. 4B illustrates an example of temperature distribution with improved uniformity along the profile of the microheater shown in FIG. 3. FIG. 4C illustrates an example of displacement distribution with improved uniformity along the profile of the microheater shown in FIG. 3. FIG. 4D illustrates an example of von Mises stress distribution with improved uniformity along the profile of the microheater shown in FIG. 3.

In some implementations, for the two electrical pads shown in each of FIGS. 4A to 4D, one electrical pad can be kept as electrically ground while a current of 60 mA can be prescribed at the other electrical pad. FIG. 4B shows the improved temperature uniformity along the profile of the microheater shown in the dotted rectangle. As shown in FIG. 4B, the major area of the microheater has the same temperature of 398° C. However, the area near the electrical pads has a slightly lower temperature (382° C.), which is equivalent to a 4% deviation. The deviation can be further reduced by adjusting the placement or material of the electrical pads. The improved uniformity of displacement shown in FIG. 4C and the improved uniformity of von Mises stress shown in FIG. 4D shows mechanical stability to the microheater.

Although the example microheater in FIGS. 2A to 4D is a fan-shaped platinum-based microheater, the method of varying coil width along the profile of a microheater can be applied to other microheaters with different geometrical topologies as well as materials to improve uniformity of temperature distribution of each of those microheaters.

In some implementations, heating may be needed for an extended area of interest. Multiple microheaters can be connected to form a microheater array to heat the extended area of interest. The arrangement of the multiple microheaters can affect the output performance of the microheater array. Another factor that affects the output performance of the microheater array is the fill factor of the microheater array, i.e., the space utilization of the microheater array.

In some implementations, the multiple microheaters in the microheater array can be connected in a series circuit configuration to provide improved uniformity of temperature distribution when compared to multiple microheaters connected in a parallel circuit configuration.

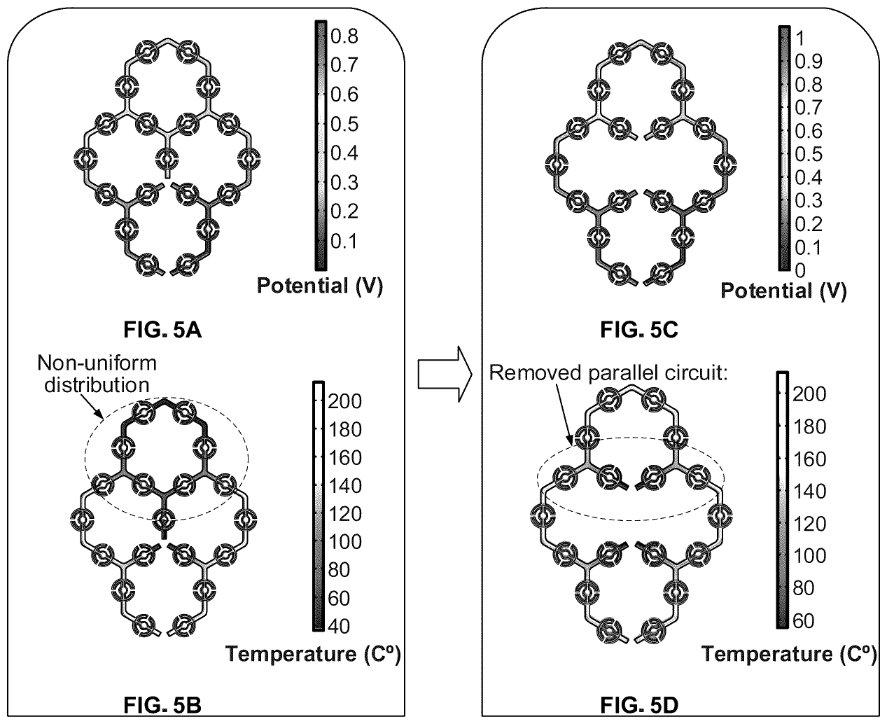

FIG. 5A illustrates an example of potential distribution of multiple concentric-shaped and platinum-based microheaters connected in a parallel circuit configuration. FIG. 5B illustrates an example of temperature distribution of the microheater array in FIG. 5A. The temperature distribution in FIG. 5B shows non-uniformity. The area shown in the dotted region in FIG. 5B has lower temperature than other regions.

FIG. 5C illustrates an example of potential distribution of multiple concentric-shaped platinum-based microheaters connected in a series circuit configuration. FIG. 5D illustrates an example of temperature distribution of the microheater array in FIG. 5C. The temperature distribution in FIG. 5D shows improved uniformity, including in the region corresponding to the dotted region in FIG. 5B. This improvement in the uniformity of temperature distribution of the microheater array is due to the removal of the parallel circuit from FIG. 5B, as shown in the dotted region in FIG. 5D.

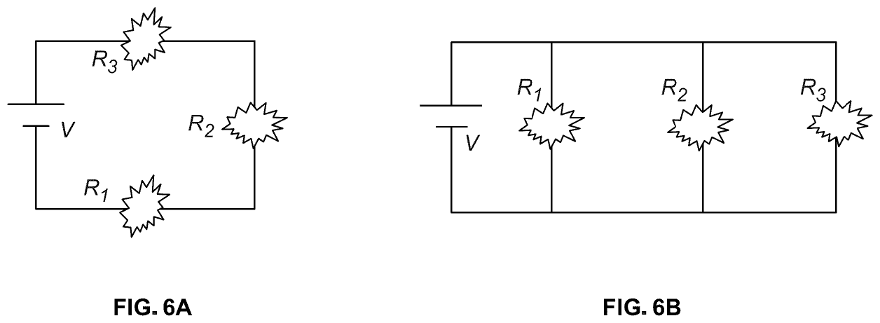

In some implementations, the current distribution of the microheater array depends on whether the configuration follows the series circuit or parallel circuit. FIG. 6A illustrates an example of the characteristics and representative schematics of series circuit. FIG. 6B illustrates an example of the characteristics and representative schematics of parallel circuit. For series circuits, the current is the same for all resistors, whereas, for parallel circuits, the input current is divided among the resistors. The characteristics of the current distribution in a microheater array with a specific circuit configuration follows the characteristics of the current distribution of the corresponding circuit. Therefore the overall output temperature of a microheater array with parallel circuit configuration can be reduced, as shown in the dotted region in FIG. 5B. In contrast, microheaters in series circuit configuration share the same amount of current and thus exhibit improved uniformity in the output temperature, once the parallel circuit is removed, as shown in FIG. 5D. Therefor a microheater array with series circuit configuration can provide high areal efficiency and improved uniformity in the output temperature.

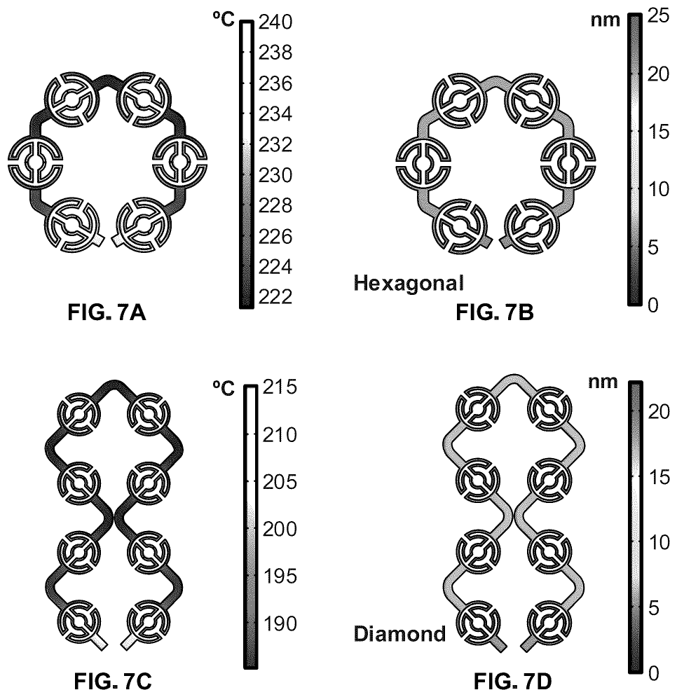

FIG. 7A illustrates an example of temperature distribution of multiple concentric-shaped platinum-based microheaters connected in a hexagonal configuration. FIG. 7B illustrates an example of displacement distribution of multiple concentric-shaped platinum-based microheaters connected in a hexagonal configuration. FIG. 7C illustrates an example of temperature distribution of multiple concentric-shaped platinum-based microheaters connected in a diamond configuration. FIG. 7D illustrates an example of displacement distribution of multiple concentric-shaped platinum-based microheaters connected in a diamond configuration. In each of these four configurations, the series circuit configuration is maintained. FIGS. 7A and 7C both show improved uniformity in temperature distribution across multiple microheaters. These configurations can be used in applications such as actuators and sensors for selectivity and temperature uniformity in large areas.

At 104, the microheater with varying coil width determined in step 102 is provided as a heating component of a MEMS based device. One example application of the microheater with varying coil width is for detection of smuggled diesel in fuel products. Using a MEMS sensor with the microheater having varying coil width can avoid the use of the marker additive to the entire fuel product to detect diesel, and therefore reducing the cost of detecting smuggled diesel in fuel products.

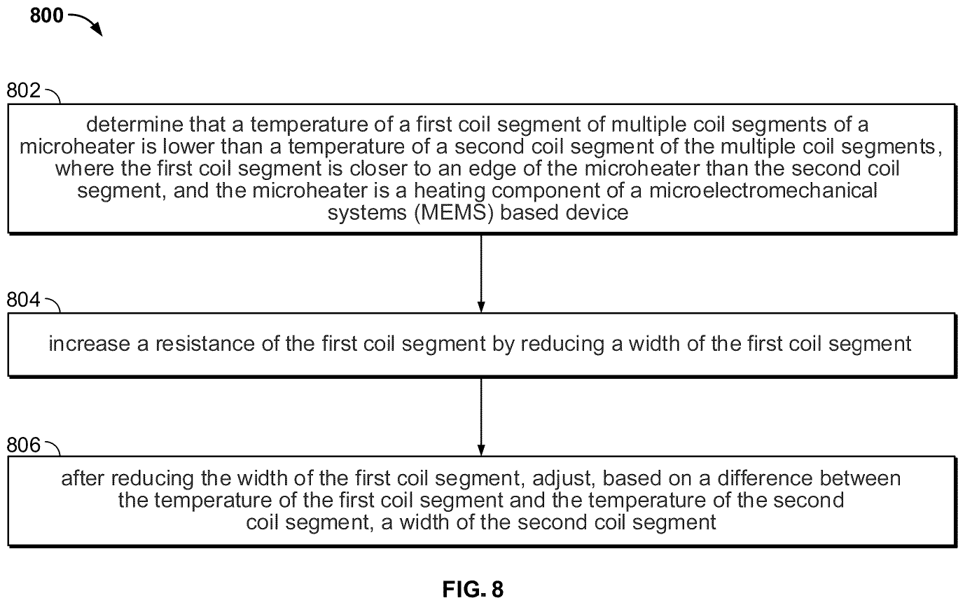

FIG. 8 illustrates an example process 800 of improving uniformity of temperature distribution of a microheater.

At 802, it is determined that a temperature of a first coil segment of multiple coil segments of a microheater is lower than a temperature of a second coil segment of the multiple coil segments, where the first coil segment is closer to an edge of the microheater than the second coil segment, and the microheater is a heating component of a microelectromechanical systems (MEMS) based device.

At 804, a resistance of the first coil segment is increased through a reduction of a width of the first coil segment.

At 806, after the reduction of the width of the first coil segment, a width of the second coil segment is adjusted based on a difference between the temperature of the first coil segment and the temperature of the second coil segment.

Certain aspects of the subject matter described here can be implemented as a method. It is determined that a temperature of a first coil segment of multiple coil segments of a microheater is lower than a temperature of a second coil segment of the multiple coil segments, where the first coil segment is closer to an edge of the microheater than the second coil segment, and the microheater is a heating component of a microelectromechanical systems (MEMS) based device. A resistance of the first coil segment is increased through a reduction of a width of the first coil segment. After the reduction of the width of the first coil segment, a width of the second coil segment is adjusted based on a difference between the temperature of the first coil segment and the temperature of the second coil segment.

Methods can include one or more of the following features.

In some implementations, adjusting the width of the second coil segment includes adjusting the width of the second coil segment using a numerical calculation.

In some implementations, the numerical calculation includes a finite element method (FEM) based numerical calculation.

In some implementations, a diameter of the wavy structure is adjusted based on a temperature of a wavy structure and the temperatures of the first coil segment and the second coil segment, where the first coil segment is coupled to an electrical pad of the microheater through a third coil segment, the third coil segment includes the wavy structure, the wavy structure includes multiple half-circled coil segments, and the diameter of the wavy structure is a diameter of each of the multiple half-circled coil segments.

In some implementations, the adjusted diameter of the wavy structure is smaller than the reduced width of the first coil segment.

In some implementations, the electrical pad is an electrical ground of the microheater.

In some implementations, the reduced width of the first coil segment is smaller than the adjusted width of the second coil segment.

In some implementations, a thickness of the microheater is one micrometer or less.

In some implementations, the microheater includes one of a fan-shaped, serpentine, concentric, and meander-patterned microheater.

In some implementations, a material of the microheater includes one of platinum, polysilicon, copper, gold, silver, and aluminum.

Certain aspects of the subject matter described here can be implemented as a method. It is determined that multiple microheaters in a microheater array have temperature variation that is larger than a preset threshold, where at least two or more microheaters of the multiple microheaters in the microheater array are connected in a parallel circuit configuration. The multiple microheaters are connected in a series circuit configuration. The multiple microheaters are provided as a heating component of a microelectromechanical systems (MEMS) based device.

Methods can include one or more of the following features.

In some implementations, the multiple microheaters includes multiple concentric microheaters.

Certain aspects of the subject matter described here can be implemented as a microheater. The microheater includes two electrical pads, two coil segments, and multiple coil segments. The two coil segments are directly coupled to the two electrical pads respectively, where each of the two coil segments includes a respective wavy structure, and each of the two wavy structures includes multiple half-circled coil segments. The multiple coil segments are coupled to the two electrical pads through the two coil segments, where the multiple coil segments includes at least a first coil segment and a second coil segment, the first coil segment is closer to an edge of the microheater than the second coil segment, and a width of the first coil segment is smaller than a width of the second coil segment.

Microheaters can include one or more of the following features.

In some implementations, a diameter of each of the multiple half-circled coil segments is smaller than the width of the first coil segment.

In some implementations, one of the two electrical pads is an electrical ground of the microheater.

In some implementations, one of the two electrical pads is configured to couple to a power source.

In some implementations, a thickness of the microheater is one micrometer or less.

In some implementations, the microheater includes one of a fan-shaped, serpentine, concentric, and meander-patterned microheater.

In some implementations, a material of the microheater includes one of platinum, polysilicon, copper, gold, silver, and aluminum.

In some implementations, the microheater is a heating component of a microelectromechanical systems (MEMS) based device.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A method, comprising:
determining that a temperature of a first coil segment of a plurality of coil segments of a microheater is lower than a temperature of a second coil segment of the plurality of coil segments, wherein the first coil segment is closer to an edge of the microheater than the second coil segment, and wherein the microheater is a heating component of a microelectromechanical systems (MEMS) based device;
increasing a resistance of the first coil segment by reducing a width of the first coil segment; and
after reducing the width of the first coil segment, adjusting, based on a difference between the temperature of the first coil segment and the temperature of the second coil segment, a width of the second coil segment.

2. The method of claim 1, wherein adjusting the width of the second coil segment comprises adjusting the width of the second coil segment using a numerical calculation.

3. The method of claim 2, wherein the numerical calculation comprises a finite element method (FEM) based numerical calculation.

4. The method of claim 1, wherein the method further comprises:
adjusting, based on a temperature of a wavy structure and the temperatures of the first coil segment and the second coil segment, a diameter of the wavy structure, wherein the first coil segment is coupled to an electrical pad of the microheater through a third coil segment, the third coil segment comprises the wavy structure, the wavy structure comprises a plurality of half-circled coil segments, and the diameter of the wavy structure is a diameter of each of the plurality of half-circled coil segments.

5. The method of claim 4, wherein the adjusted diameter of the wavy structure is smaller than the reduced width of the first coil segment.

6. The method of claim 4, wherein the electrical pad is an electrical ground of the microheater.

7. The method of claim 1, wherein the reduced width of the first coil segment is smaller than the adjusted width of the second coil segment.

8. The method of claim 1, wherein a thickness of the microheater is one micrometer or less.

9. The method of claim 1, wherein the microheater comprises one of a fan-shaped, serpentine, concentric, and meander-patterned microheater.

10. The method of claim 1, wherein a material of the microheater comprises one of platinum, polysilicon, copper, gold, silver, and aluminum.

11. A method, comprising:
determining that a plurality of microheaters in a microheater array have temperature variation that is larger than a preset threshold, wherein at least two or more microheaters of the plurality of microheaters in the microheater array are connected in a parallel circuit configuration;
connecting the plurality of microheaters in a series circuit configuration; and
providing the plurality of microheaters as a heating component of a microelectromechanical systems (MEMS) based device.

12. The method of claim 11, wherein the plurality of microheaters comprises a plurality of concentric microheaters.

13. A microheater, comprising:
two electrical pads;
two coil segments directly coupled to the two electrical pads respectively, wherein each of the two coil segments comprises a respective wavy structure, and each of the two wavy structures comprises a plurality of half-circled coil segments; and
a plurality of coil segments coupled to the two electrical pads through the two coil segments, wherein:
the plurality of coil segments comprises at least a first coil segment and a second coil segment;
the first coil segment is closer to an edge of the microheater than the second coil segment; and
a width of the first coil segment is smaller than a width of the second coil segment.

14. The microheater of claim 13, wherein a diameter of each of the plurality of half-circled coil segments is smaller than the width of the first coil segment.

15. The microheater of claim 13, wherein one of the two electrical pads is an electrical ground of the microheater.

16. The microheater of claim 13, wherein one of the two electrical pads is configured to couple to a power source.

17. The microheater of claim 13, wherein a thickness of the microheater is one micrometer or less.

18. The microheater of claim 13, wherein the microheater comprises one of a fan-shaped, serpentine, concentric, and meander-patterned microheater.

19. The microheater of claim 13, wherein a material of the microheater comprises one of platinum, polysilicon, copper, gold, silver, and aluminum.

20. The microheater of claim 13, wherein the microheater is a heating component of a microelectromechanical systems (MEMS) based device.
